(19) United States
(12) Patent Application Publication
(10) Pub. No.: US 2024/0038833 A1
(43) Pub. Date: Feb. 1, 2024

(54) CARBON MOLD FOR DRAM CAPACITOR

(71) Applicant: Applied Materials, Inc., Santa Clara, CA (US)

(72) Inventors: Fredrick Fishburn, Aptos, CA (US); Tomohiko Kitajima, San Jose, CA (US); Qian Fu, Pleasanton, CA (US); Srinivas Guggilla, San Jose, CA (US); Hang Yu, San Jose, CA (US); Jun Feng, Santa Clara, CA (US); Shih Chung Chen, Cupertino, CA (US); Lakmal C. Kalutarage, San Jose, CA (US); Jayden Potter, Santa Clara, CA (US); Karthik Janakiraman, San Jose, CA (US); Deenesh Padhi, Sunnyvale, CA (US); Yifeng Zhou, Santa Clara, CA (US); Yufeng Jiang, Santa Clara, CA (US); Sung-Kwan Kang, Santa Clara, CA (US)

(73) Assignee: Applied Materials, Inc., Santa Clara, CA (US)

(21) Appl. No.: 18/222,086

(22) Filed: Jul. 14, 2023

Related U.S. Application Data
(60) Provisional application No. 63/393,089, filed on Jul. 28, 2022.
(60) Provisional application No. 63/401,824, filed on Aug. 29, 2022.

(51) Int. Cl. H10B 12/00

(52) U.S. Cl. CPC H01L 28/91; H01L 28/92; H10B 12/03; H10B 12/30

(57) ABSTRACT

Memory devices and methods of forming memory devices are described. Methods of forming electronic devices are described where carbon is used as the removable mold material for the formation of a DRAM capacitor. A dense, high-temperature (500° C. or greater) PECVD carbon material is used as the removable mold material, e.g., the core material, instead of oxide. The carbon material can be removed by isotropic etching with exposure to radicals of oxygen (O₂), nitrogen (N₂), hydrogen (H₂), ammonia (NH₃), and combinations thereof.

### CROSS-REFERENCE TO RELATED APPLICATIONS

This application claims priority to United States Provisional Application No. 63/393,089, filed Jul. 28, 2022, and to United States Provisional Application No. 63/401,824, filed Aug. 29, 2022, the entire disclosures of which are hereby incorporated by reference herein.

### TECHNICAL FIELD

Embodiments of the present disclosure pertain to the field of electronic devices and electronic device manufacturing. More particularly, embodiments of the disclosure provide electronic devices including carbon as a removable mold material in the formation of DRAM capacitors.

### BACKGROUND

DRAM manufacturing is a highly competitive business. Dynamic random-access memories (DRAMs) can be programmed to store a voltage which represents one of two binary values but require periodic reprogramming or “refreshing” to maintain this voltage for more than very short periods of time. DRAM memory circuits are manufactured by replicating billions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

There is continuous pressure to decrease the size of individual DRAM cells and to increase memory cell density to allow more memory to be squeezed onto a single memory chip, especially for densities greater than 8 Gigabits. Limitations on cell size reduction include the passage of both bitlines and word lines through the cell, the size of the cell capacitor, and the compatibility of array devices with non-array devices.

A significant barrier to further reduction in DRAM sizes is maintaining sufficient cell capacitances with good leakage and low density of cell-to-cell shorts. The average space between cells is 15 nm to 20 nm in order to fit the high-k dielectric and have at least a 10 nm margin against cell-to-cell leakage.

Additionally, another difficulty in reducing DRAM sizes is the small pitch of the capacitor, which is on a hex layout at a pitch equal to the bit line (BL) pitch. The high aspect ratio (HAR) etch fixed the gap between the holes to satisfy the 12 nm final minimum gap means that the hole size is rapidly decreasing. The etch profile needs to be as vertical as possible, which requires etch mask materials with high selectivity. Thus far, silicon oxide (SiOₓ) has been used as the film that is etched in high aspect ratio (HAR) capacitors and later removed to make use of the outer surface of the titanium nitride (TiN) electrode to form the capacitor on. This is called “the mold” oxide, or “the core”.

The oxide is isotropically etched during the pre-clean before the bottom electrode, e.g., TiN, is deposited. While this wet etch can be used to help straighten the tapered etch profile, it also means that the initial critical dimension (CD) needs to be smaller to account for the growth in CD after the clean, pushing the aspect ratio for HAR reactive ion etching (RIE) even further.

The oxide mold removal needs to be done isotropically, and strong hydrofluoric acid (HF) is used to remove the mold oxide with increased selectivity to the support layers (SiN based) in the mold. Even so, 100 Å to 300 Å of the support layer is removed during this HF etch process, which means that the deposited thickness needs to be 200 Å to 600 Å thicker, making HAR reactive ion etching (RIE) harder. Accordingly, there is a need in the art for materials and methods of forming DRAM capacitors that avoid these problems.

### SUMMARY

One or more embodiments of the disclosure are directed to a semiconductor device. In one or more embodiments, the semiconductor device comprises: a plurality of pillars extending through a mold stack, the mold stack comprising a first core carbon layer on an etch stop layer on a substrate, a first support layer on a top surface of the first core carbon layer, a second core carbon layer on the first support layer, a second support layer on the second core carbon layer, and a hardmask layer on the second support layer.

Additional embodiments of the disclosure are directed to a method of forming a semiconductor device. In one or more embodiments, the method comprises: forming a mold stack on an etch stop layer on a substrate, the mold stack comprising a first core carbon layer on an etch stop layer on a substrate, a first support layer on a top surface of the first core carbon layer, a second core carbon layer on the first support layer, a second support layer on the second core carbon layer, a hardmask layer on the second support layer, and a hardmask opening layer on the hard mask layer; etching a plurality of openings in the mold stack, the plurality of openings extending from a top surface of the hardmask opening layer to a top surface of the substrate; conformally depositing an electrode layer in the plurality of openings; depositing a core layer on the electrode layer; performing a high aspect ratio etch to remove a portion of the first support layer and a portion of the second support layer; and exposing the mold stack to isotropic etching to remove the first core carbon layer and the second core carbon layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments;

FIG. 2 illustrates a cross-section view of a DRAM device according to one or more embodiments;

FIG. 3 illustrates a cross-section view of a DRAM device according to one or more embodiments;

FIG. 4A illustrates a top view of the DRAM device of FIG. 3 according to one or more embodiments;

FIG. 4B illustrates a top view of the DRAM device of FIG. 3 according to one or more alternative embodiments;

FIG. 5 illustrates a cross-section view of a DRAM device according to one or more embodiments; and

FIG. 6 illustrates a cross-section view of a DRAM device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

As used herein, the term “capacitor” refers to an electrical component of a memory cell. A capacitor has two electrical conductors separated by electrically insulating material.

As used herein, the phrase “amorphous hydrogenated carbon,” also referred to as “amorphous carbon” and denoted as a-C:H, refers to a carbon material with no long-range crystalline order which may contain a substantial hydrogen content, for example on the order of about 10 to 45 atomic %. Amorphous carbon is used as a hard mask material in semiconductor applications because of its chemical inertness, optical transparency, and good mechanical properties.

One or more embodiments provide DRAM capacitors with carbon as the removable core, or as the removable mold material, instead of oxide. Other embodiments provide methods of manufacturing DRAM capacitors where carbon is the removable core material. In one or more embodiments, a dense, high temperature (500° C. or greater) plasma enhanced chemical vapor deposition (PECVD) carbon material is used as the removable mold material instead of an oxide material.

In one or more embodiments, a carbon deposition process which can deposit on SiN-based films used for etch stop layer and those used as the mid support layer is required. Thus, in one or more embodiments, SiN based films that can be deposited on carbon are required.

In one or more embodiments, titanium nitride (TiN) or other metal-nitride films, which can be deposited on the carbon and still retain Rs and electrode properties necessary to form the DRAM capacitor are required.

In one or more embodiments, a suitable hard mask film with very high selectivity to the carbon etch chemistry and the etches to “punch” through the mid support layer are required.

In one or more embodiments, an isotropic etch process to remove the carbon by way of small, high aspect ratio openings in the support layers is required.

In one or more embodiments, 400 nm to 600 nm of 500° C. PECVD carbon is deposited on the standard existing silicon boronitride (SiBN) etch stop layer. A film of carbon doped silicon nitride (SiCN), about 15 nm, is deposited as the mid-support layer. In some embodiments one or more of silicon oxide (SiOx), or silicon oxynitride (SiON) may be the mid and upper support layers. In some embodiments 3 nm to 10 nm, or about 5 nm of silicon oxynitride (SiON followed by the remaining being silicon oxide (SiOx) may be the mid and upper support layers. A layer of about 300 nm to 400 nm 500° C. PECVD carbon is deposited on the carbon doped silicon nitride (SiCN) to form the upper mold carbon. A layer of about 80 nm to about 100 nm of carbon doped silicon nitride (SiCN) is then deposited on the upper core carbon to form the top support. In one or more embodiments, the carbon deposition process advantageously forms an adhesion to the SiN based films to prevent it from peeling. In one or more embodiments, the carbon doped silicon nitride (SiCN) deposition process advantageously forms an adhesion to the carbon to prevent it from peeling, while, in other applications, a silicon nitride (SiN) film can be used.

In one or more embodiments, 400° C. to 500° C. atomic layer deposition (ALD) titanium tetrachloride (TiCl₄) is used to deposit low resistivity (<500 μohm-cm) TiN inside the HAR carbon holes.

In one or more embodiments, boron nitride (BN) based films are used as the hard mask film with little to no silicon in the film, thus permitting very small holes which do not “clog” during the HAR etch processes. In one or more embodiments, the etch chamber is used to open holes in the support layer after bottom electrode, e.g., TiN, formation is used to isotropically remove part or all the mold carbon using a combination of O and NH radicals.

The embodiments of the disclosure are described by way of the Figures, which illustrate devices (e.g., DRAM) and processes for forming DRAMs in accordance with one or more embodiments of the disclosure. The processes shown are merely illustrative possible uses for the disclosed processes, and the skilled artisan will recognize that the disclosed processes are not limited to the illustrated applications.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the Surface through which the implantation takes place. Thus, the regions illustrated in the figures are schematic in nature and their shapes may be not intended to illustrate the actual shape of a region of a device and are not intended to limit the scope of example embodiments.

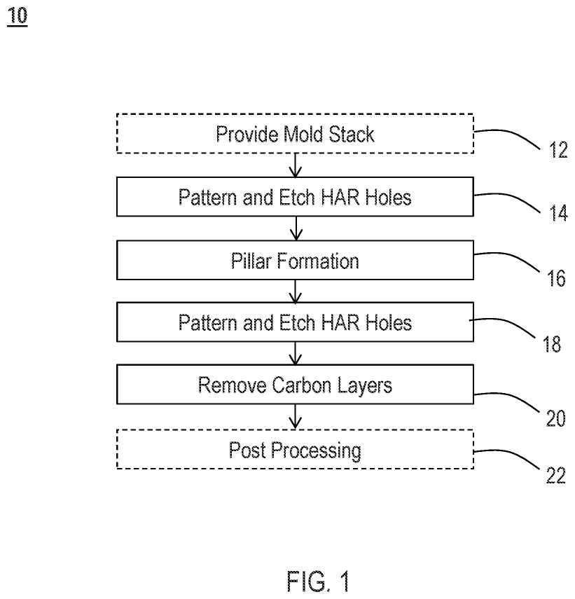

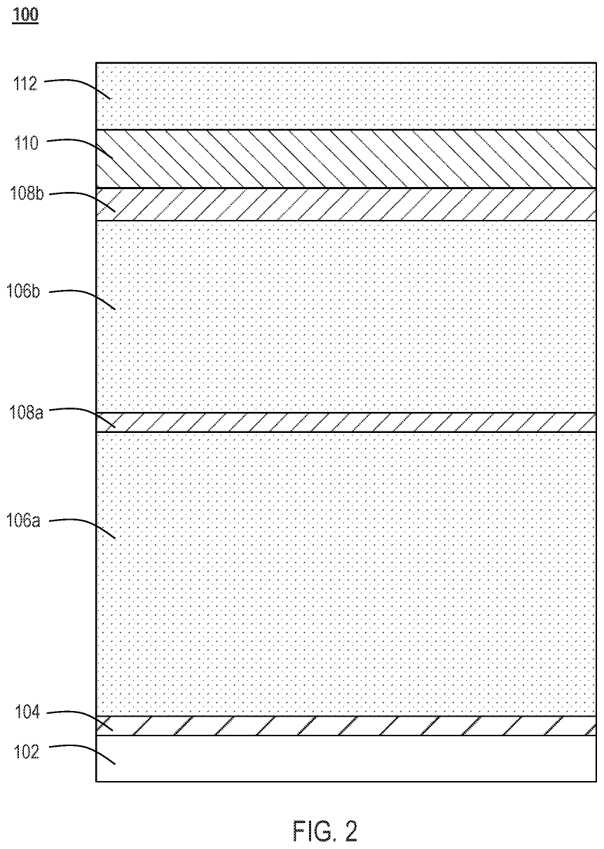

FIG. 1 illustrates a process flow diagram for a method 10 for forming a semiconductor device in accordance with some embodiments of the present disclosure. FIGS. 2-6 illustrate cross-sectional views of a semiconductor device according to one or more embodiments. The method 10 is described below with respect to FIGS. 2-6. The method 10 may be part of a multi-step fabrication process of a semiconductor device, a DRAM in particular.

In one or more embodiments, the method 10 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

Referring to FIG. 1, at operation 12 of method 10, a mold stack for a capacitor is provided. As used in this specification and the appended claims, the term “provided” means that the mold stack is made available for processing (e.g., positioned in a processing chamber). In one or more embodiments, the mold stack is first formed by a series of deposition steps, as described below with respect to FIG. 2. At operation 14, the holes are etched. At operation 16, the pillars are formed (i.e., lower electrode deposition). At operation 18, HAR holes are patterned and etched in the support layers. At operation 20, the carbon layers are isotropically removed. At operation 22, the stack may be optionally post-processed.

FIG. 2 illustrates a cross-section view of a mold stack of layers used in the formation of a DRAM capacitor. In one or more embodiments, the stack 100 comprises an etch stop layer 104 formed on a substrate 102. The etch stop layer 104 may comprise any suitable material known to the skilled artisan. In one or more embodiments, the etch stop layer 104 comprises one or more of a conformal layer of dielectric; SiN, SiCN, SiBN, SiON, and combinations thereof. The etch stop layer 104 may be deposited by any suitable technique known to the skilled artisan. In one or more embodiments, the etch stop layer 104 is deposited using a technique selected from CVD, PECVD, ALD deposition. The etch stop layer 104 may have any suitable thickness known to the skilled artisan. In one or more embodiments, the etch stop layer has a thickness in a range of from 0.7 nm to 70 nm, including in a range of from 1.75 nm to 28 nm, including in a range of from 3.5 nm to 14 nm.

In one or more embodiments, a first core carbon layer 106a is deposited on the top surface of the etch stop layer 104.

In one or more embodiments, the first core carbon layer 106a may be deposited at very high temperatures and have low hydrogen (H) content. In one or more embodiments, the first core carbon layer 106a comprises a dense, high temperature (500° C. or greater) plasma enhanced chemical vapor deposition (PECVD) carbon material. In some embodiments, the first core carbon layer 106a may be largely sp², resulting in lower density and modulus, which can, in some circumstances lead to an advantageous higher lateral etch rate or improved etch rate for RIE or isotropic removal etching.

In one or more embodiments, a high sp³ amorphous carbon material is advantageously deposited as the first core carbon layer 106a. In one or more embodiments, the deposition is done at low temperatures using diamondoid precursors.

In one or more embodiments, to achieve greater etch selectivity, the density and, more importantly, the Young's modulus of the first core carbon layer 106a is improved. One of the main challenges in achieving greater etch selectivity and improved Young's modulus is the high compressive stress of such a film making it unsuitable for applications owing to the resultant high wafer bow. Hence, there is a need for carbon (diamond-like) films with high-density and modulus (e.g., higher sp³ content, more diamond-like) with high etch selectivity along with low stress (e.g., <−500 MPa).

As used herein, the terms “diamond-like” and/or “diamonoid” refer to a class of chemical compounds having a diamond crystal lattice. Diamondoids may include one or more carbon cages (e.g., adamantine, diamantine, triamantane, and high polymantanes). Diamondoids of the adamantine series are hydrocarbons composed of fused cyclohexane rings which form interlocking cage structures. Diamondoids may be substituted and unsubstituted caged compounds. These chemical compounds may occur naturally or can be synthesized. Diamondoids have a high sp³ content and also have a high C:H ratio. In the general sense, diamond-like carbon materials are strong, stiff structures having dense 3D networks of covalent bonds.

In one or more embodiments, the density of the first core carbon layer 106a and the second core carbon layer 106b is greater than 1.8 g/cc, including greater than 1.9 g/cc, and including greater than 2.0 g/cc. In one or more embodiments, the density of the first core carbon layer 106a and the second core carbon layer 106b is about 2.1 g/cc. In one or more embodiments, the density of the first core carbon layer 106a and the second core carbon layer 106b is in a range of about greater than 1.8 g/cc to about 2.2 g/cc. In one or more embodiments, the density of the first core carbon layer 106aand the second core carbon layer 106b is greater than about 2.2 g/cc.

Referring again to FIG. 2, in one or more embodiments, the first core carbon layer 106a may have any suitable thickness known to the skilled artisan. In one or more embodiments, the first core carbon layer 106a has a thickness in a range of from 60 nm to 6000 nm, including in a range of from 150 nm to 2400 nm, including in a range of from 300 nm to 1200 nm, and including a range of from 400 nm to 700 nm.

In one or more embodiments, the first core carbon layer 106a may be deposited by any suitable means known to the skilled artisan. In one or more embodiments, the first core carbon layer 106a is deposited by plasma enhanced chemical vapor deposition (PECVD). In one or more embodiments, the PECVD may be performed at any suitable temperature. In specific embodiments, the PECVD deposition of the first core carbon layer 106a is conducted at a temperature in a range of from 300° C. to 700° C., including in a range of from 400° C. to 600° C., including in a range of from 450° C. to 550° C.

With reference to FIG. 2, a first support layer 108a is deposited on the top surface of the first core carbon layer 106a. The first support layer 108a may comprise any suitable material known to the skilled artisan. In one or more embodiments, the first support layer 108a comprises a dielectric material.

As used herein, the term “dielectric material” refers to a layer of material that is an electrical insulator that can be polarized in an electric field. In one or more embodiments, the dielectric layer comprises one or more of oxides, carbon doped oxides, silicon oxide (SiOₓ), silicon nitride (SiN), silicon oxide/silicon nitride, carbides, oxycarbides, nitrides, oxynitrides, oxycarbonitrides, polymers, phosphosilicate glass, fluorosilicate (SiOF) glass, organosilicate glass (SiOCH), silicon carbo nitride (SiCN). In one or more embodiments, the dielectric layer includes, without limitation, furnace, CVD, PVD, ALD and spin-on-coat (SoC) deposited films. In one or more embodiments, the dielectric layer may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the dielectric. In one or more specific embodiments, the first support layer 108a comprises silicon nitride (SiN). The silicon nitride (SiN) may be doped or undoped. In some embodiments, the silicon nitride is doped with carbon (SiCN).

In one or more embodiments, the first support layer 108a may have any suitable thickness. In some embodiments, the first support layer 108a has a thickness in a range of from 2 nm to 100 nm, including in a range of from 5 nm to 50 nm, including in a range of from 10 nm to 20 nm. There may also exist 2 or more support layers within the Carbon mold to balance the need for increased mechanical support with the increased complexity and difficulty of the reactive ion etching (RIE) of the film stack.

Referring to FIG. 2, a second core carbon layer 106b is deposited on a top surface of the first support layer 108a. The second core carbon layer 106b may comprise any suitable material known to the skilled artisan. In some embodiments, the second core carbon layer 106b comprises the same material as the first core carbon layer 106a as described above.

In one or more embodiments, the second core carbon layer 106b may be deposited at very high temperatures and have low hydrogen (H) content. In one or more embodiments, the second core carbon layer 106b comprises a dense, high temperature (500° C. or greater) plasma enhanced chemical vapor deposition (PECVD) carbon material. In some embodiments, the second core carbon layer 106b may be largely sp², resulting in lower density and modulus, which can, in some circumstances lead to lower etch selectivity and pattern integrity. Modulus is a measurement of the mechanical strength of the film.

In one or more embodiments, a high spa amorphous carbon material is advantageously deposited as the second core carbon layer 106b. In one or more embodiments, the deposition is done at low temperatures using diamondoid precursors.

In one or more embodiments, the second core carbon layer 106b may have any suitable thickness known to the skilled artisan. In one or more embodiments, the second core carbon layer 106b has a thickness that is less than the thickness of the first core carbon layer 106a. In one or more embodiments, the second core carbon layer 106b has a thickness in a range of from 45 nm to 4500 nm, including in a range of from 110 nm to 1800 nm, and including in a range of from 225 nm to 900 nm.

In one or more embodiments, the second core carbon layer 106b may be deposited by any suitable means known to the skilled artisan. In one or more embodiments, the second core carbon layer 106b is deposited by plasma enhanced chemical vapor deposition (PECVD). In one or more embodiments, the PECVD may be performed at any suitable temperature. In specific embodiments, the PECVD deposition of the second core carbon layer 106b is conducted at a temperature in a range of from 300° C. to 700° C., including in a range of from 400° C. to 600° C., including in a range of from 450° C. to 550° C.

With reference to FIG. 2, a second support layer 108b is deposited on a top surface of the second core carbon layer 106b. The second support layer 108b may comprise any suitable material known to the skilled artisan. In one or more embodiments, the second support layer 108b comprises the same material as the first support layer 108a. In one or more embodiments, the second support layer 108b comprises a dielectric material.

In one or more embodiments, the second support layer 108b comprises one or more of oxides, carbon doped oxides, silicon oxide (SiOₓ), silicon dioxide (SiO₂), silicon nitride (SiN), silicon oxide/silicon nitride, carbides, oxycarbides, nitrides, oxynitrides, oxycarbonitrides, polymers, phosphosilicate glass, fluorosilicate (SiOF) glass, organosilicate glass (SiOCH), silicon carbo nitride (SiCN). In one or more specific embodiments, the second support layer 108b comprises silicon nitride (SiN). The silicon nitride (SiN) may be doped or undoped. In some embodiments, the silicon nitride is doped with carbon (SiCN). The top support layer may also include all or a part of the hard mask film which remains after the RIE etch.

In one or more embodiments, the second support layer 108b may have any suitable thickness. In one or more embodiments, the second support layer 108b has a thickness greater than the thickness of the first support layer 108a. In some embodiments, the top support layer 108b has a thickness in a range of from 8 nm to 800 nm, including in a range of from 20 nm to 300 nm, including in a range of from 30 nm to 150 nm. Without intending to be bound by theory, it is thought that deposition of the first core carbon layer 106a and deposition of the second core carbon layer 106b forms an adhesion to the lower etch stop layer 104 and the first support layer 108a, respectively, which advantageously prevent the first support layer 108a and the second support layer 108b from separating or peeling.

Referring to FIG. 2, a hardmask layer 110 is deposited on a top surface of the second support layer 108b. The hardmask layer 110 may comprise any suitable material known to the skilled artisan. In one or more embodiments, the hardmask layer 110 comprises one or more of silicon oxide (SiOₓ), silicon carbide (SiC), Boron and boronitride (BN). In one or more specific embodiments, the hardmask layer 110 comprises boronitride (BN).

The hardmask layer 110 may have any suitable thickness. In one or more embodiments, the hardmask layer 110 has a thickness in a range of from 20 nm to 1000 nm, including in a range of from 30 nm to 500 nm, including in a range of from 50 nm to 300 nm.

With reference to FIG. 2, a hardmask open layer 112 is deposited on a top surface of the hardmask layer 110. The hardmask open layer 112 may comprise any suitable material. In one or more embodiments, the hardmask open layer 112 comprises carbon or silicon oxide (SiOₓ). In some embodiments, the hardmask open layer 112 comprises the same material as the first core carbon layer 106a. In other embodiments, the hardmask open layer 112 comprises the same material as the second core carbon layer 106b. The hardmask open layer 112 may have any suitable thickness. In one or more embodiments, the hardmask open layer 112 has a thickness in a range of from 20 nm to 1000 nm, including in a range of from 30 nm to 500 nm, including in a range of from 50 nm to 300 nm.

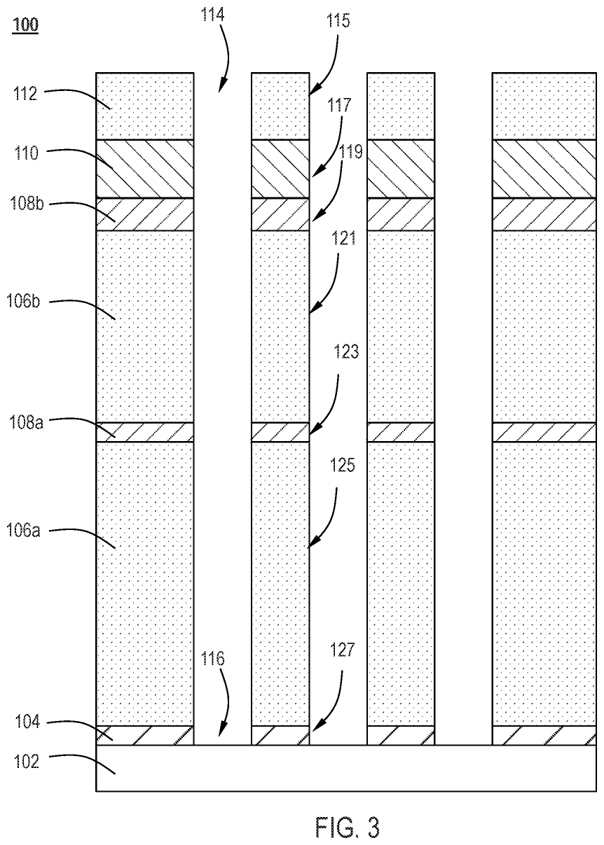

FIG. 3 illustrates a cross-section view 100 of a mold stack of layers used in the formation of a DRAM capacitor having a plurality of openings 114 etched therein. Referring to FIG. 1 and FIG. 3, at operation 14, in one or more embodiments, a plurality of openings 114 are formed in the stack by etching from a top surface of the hardmask open layer 112 through the hardmask layer 110, through the second support layer 108b, through the second core carbon layer 106b, through the first support layer 108a, through the first core carbon layer 106a, and through the etch stop layer 104 to expose a top surface of the substrate 102. Thus, in one or more embodiments, each of the plurality of openings 114 extends from a top surface of the hardmask open layer 112 to the top surface of the substrate 102.

In one or more embodiments, sidewall surfaces 115, 117, 119, 121, 123, 125, 127, and bottom 116 are formed within the opening 114 of the stack. In one or more embodiments, the opening 114 extends from a top surface of the hardmask open layer 112 through to a bottom surface of the substrate 102.

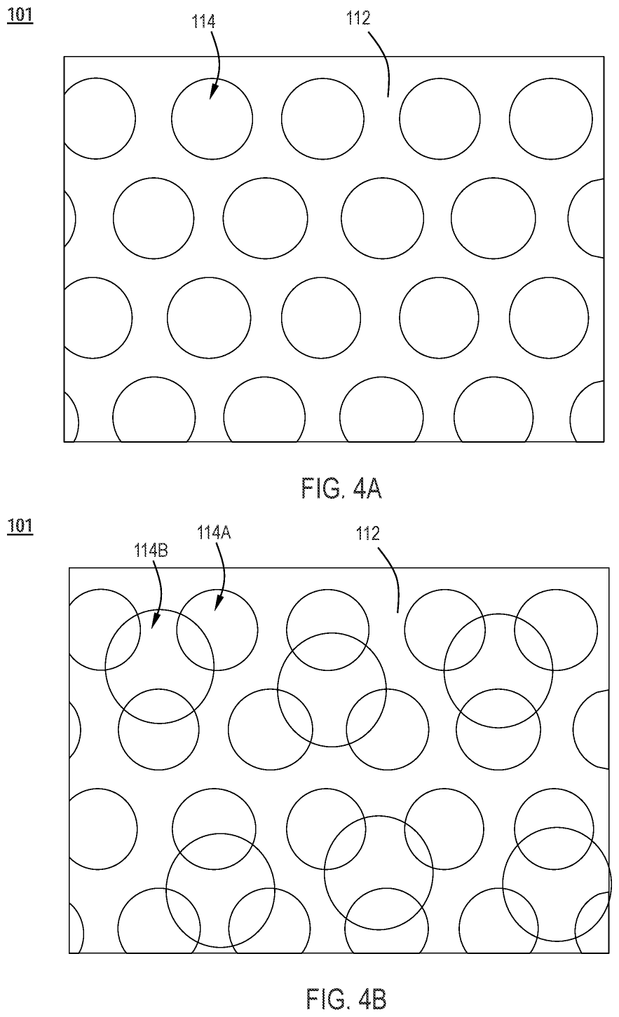

FIG. 4A illustrates a top view of the DRAM device of FIG. 3 according to one or more embodiments. The openings 114 are seen in the hardmask open layer 112.

FIG. 4B illustrates a top view of the DRAM device of FIG. 3 according to one or more alternative embodiments. The openings 114A and 114B are seen in the hardmask open layer 112. In one or more embodiments, the second HARC pattern hole or opening 114B size is larger than the first HARC pattern hole or opening 114A and only one-third the number of holes openings 114B are present compared to the number of openings 114A.

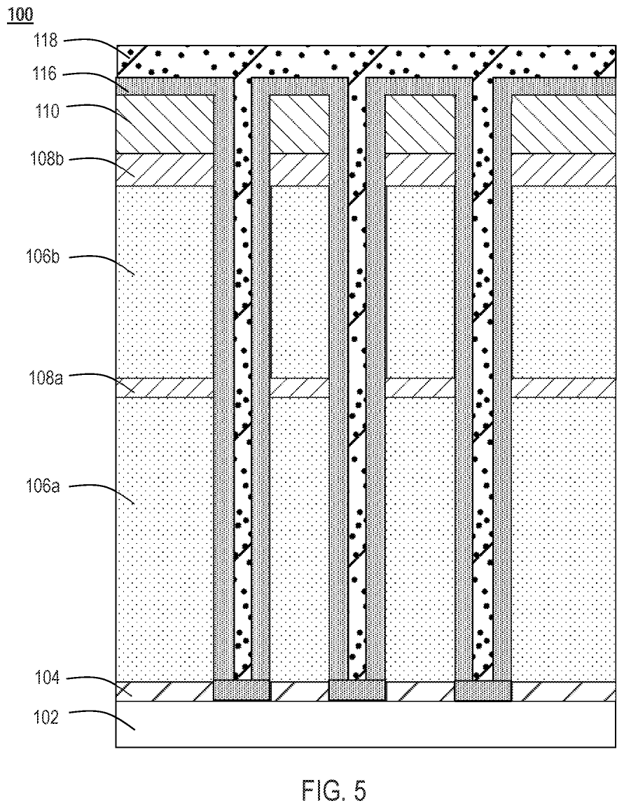

FIG. 5 illustrates a cross-section view 100 of a mold stack of layers used in the formation of a DRAM capacitor where a plurality of openings 114 has been filled to form the pillars. With reference to FIG. 1 and FIG. 5, at operation 16, a pillar lower electrode layer 116 may be deposited in the plurality of openings 114 by any suitable technique known to the skilled artisan. In some embodiments, the pillar lower electrode layer 116 may be deposited by atomic layer deposition (ALD).

The pillar lower electrode layer 116 may comprise any suitable material known to the skilled artisan. In one or more embodiments, the pillar lower electrode layer 116 comprises one or more of titanium (Ti), titanium nitride (TiN), tantalum (Ta), tantalum nitride (TaN), or tungsten (W). In one or more embodiments, 400° C. to 500° C. atomic layer deposition (ALD) titanium nitride (TiN) using titanium tetrachloride (TiCl4) is used to deposit low resistivity (<500 μOhm-cm) TiN inside the HAR openings 114.

In one or more embodiments, the pillar lower electrode layer 116 is conformally deposited in each of the plurality of openings 114. As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate. In one or more embodiments, the pillar lower electrode layer 116 has a thickness in a range of from 1 nm to 50 nm, including a range of from 3 nm to 20 nm, including a range of from 4 nm to 10 nm. The film may partially or fully fill the hole.

With reference to FIG. 5, a pillar core layer 118 is deposited in the plurality of openings 114 on the pillar lower electrode layer 116. The pillar core layer 118 may be deposited by any suitable means known to the skilled artisan including, but not limited to, ALD, CVD, PVD, and the like. In one or more embodiments, the deposition of the pillar core layer 118 is a final gap fill process. In one or more embodiments, the pillar core layer 118 has a thickness in a range of from 1 nm to 50 nm, including a range of from 3 nm to 20 nm, including a range of from 4 nm to 10 nm. The film may partially or fully fill the hole.

The pillar core layer 118 may comprise any suitable material known to the skilled artisan. In one or more embodiments, the pillar core layer 118 comprises polysilicon, oxides, carbon doped oxides, silicon dioxide (SiO₂), silicon nitride (SiN), silicon oxide/silicon nitride, carbides, oxycarbides, nitrides, oxynitrides, oxycarbonitrides, polymers, phosphosilicate glass, spin on dielectric (SOD) glass, organosilicate glass (SiOCH), silicon carbo nitride (SiCN).

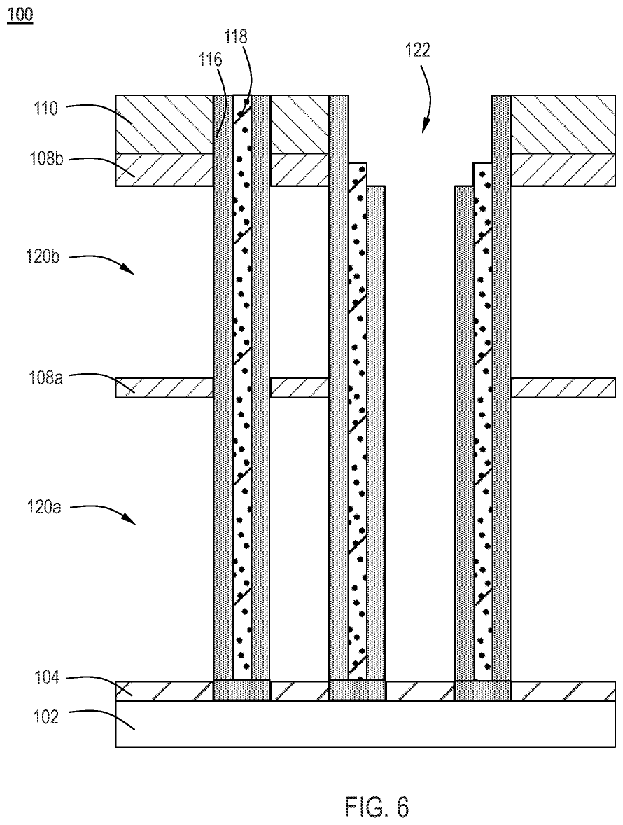

FIG. 6 illustrates a cross-section view 100 of a mold stack of layers used in the formation of a DRAM capacitor where the first core carbon layer 106a and the second core carbon layer 106b have been removed. Referring to FIG. 1 and FIG. 6, at operation 18, high aspect ratio (HAR) holes are patterned and etched in the support layers 108a, 108b. In one or more embodiments, the etching comprises reactive ion etching (RIE). In one or more embodiments, an etch chamber is used to open holes in the support layers 108a, 108b after pillar lower electrode layer 116 formation.

At operation 20, the first core carbon layer 106a and the second core carbon layer 106b are removed by isotropic etching to form a first core opening 120a and a second core opening 120b. In one or more embodiments, the first core carbon layer 106a and the second core carbon layer 106b are removed by isotropic etching using a suitable chemistry of nitrogen (N), hydrogen (H), oxygen (O₂) and/or ammonia (NH₃). In one or more embodiments, all of the mold carbon is isotropically removed using a combination of O, N, H, and NH radicals.

In one or more embodiments, the first core carbon layer 106a and the second core carbon layer 106b can be isotropically removed in the same chamber as the etching of the support layers 108a, 108b, saving cost and eliminating wet process which can cause pattern collapse.

In the embodiment shown in method 10 of FIG. 1, the device may be optionally post-processed at operation 22. The optional post-processing operation 22 can be, for example, a process to modify film properties (e.g., annealing or plasma treatment) or a further film deposition process prior to the eventual deposition of suitable dielectric material by ALD and/or CVD processes to form the DRAM Capacitor.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A semiconductor device comprising:
a plurality of pillars extending through a mold stack, the mold stack comprising a first core carbon layer on an etch stop layer on a substrate, a first support layer on a top surface of the first core carbon layer, a second core carbon layer on the first support layer, a second support layer on the second core carbon layer, and a hardmask layer on the second support layer.

2. The semiconductor device of claim 1, wherein the first core carbon layer and the second core carbon layer independently comprise a diamond-like carbon material.

3. The semiconductor device of claim 2, wherein the diamond-like carbon material has a sp³ content greater than 40 percent.

4. The semiconductor device of claim 1, wherein the first support layer and the second support layer independently comprise one or more of oxides, carbon doped oxides, silicon dioxide (SiO₂), silicon nitride (SiN), silicon oxide/silicon nitride, carbides, oxycarbides, nitrides, oxynitrides, oxycarbonitrides, polymers, phosphosilicate glass, fluorosilicate (SiOF) glass, organosilicate glass (SiOCH), or silicon carbo nitride (SiCN).

5. The semiconductor device of claim 1, wherein the first support layer and second support layer comprise silicon carbonitride (SiCN).

6. The semiconductor device of claim 1, wherein the first support layer comprises silicon nitride (SiN).

7. The semiconductor device of claim 1, wherein the hardmask layer comprises one or more of silicon oxide (SiOx), silicon carbide (SiC), carbon doped hydrogenated silicon oxide (SiOCH), boron, and boron nitride (BN).

8. The semiconductor device of claim 7, wherein the hardmask layer comprises boron nitride (BN).

9. The semiconductor device of claim 1, wherein the plurality of pillars comprise an electrode layer and a core layer.

10. The semiconductor device of claim 9, wherein the electrode layer comprises one or more of titanium (Ti), titanium nitride (TiN), tantalum (Ta), tantalum nitride (TaN).

11. The semiconductor device of claim 9, wherein the core layer comprises one or more of polysilicon, oxides, carbon doped oxides, silicon dioxide (SiO₂), silicon nitride (SiN), silicon oxide/silicon nitride, carbides, oxycarbides, nitrides, oxynitrides, oxycarbonitrides, polymers, phosphosilicate glass, spin on dielectric (SOD) glass, organosilicate glass (SiOCH), and silicon carbo nitride (SiCN).

12. The semiconductor device of claim 1, wherein the etch stop layer comprises SiN, SiCN, SiBN, SiON, and combinations thereof.

13. A method of forming a semiconductor device, the method comprising:
forming a mold stack on an etch stop layer on a substrate, the mold stack comprising a first core carbon layer on an etch stop layer on a substrate, a first support layer on a top surface of the first core carbon layer, a second core carbon layer on the first support layer, a second support layer on the second core carbon layer, a hardmask layer on the second support layer, and a hardmask opening layer on the hard mask layer;
etching a plurality of openings in the mold stack, the plurality of openings extending from a top surface of the hardmask opening layer to a top surface of the substrate;
conformally depositing an electrode layer in the plurality of openings;
depositing a core layer on the electrode layer;
performing a high aspect ratio etch to remove a portion of the first support layer and a portion of the second support layer; and
exposing the mold stack to isotropic etching to remove the first core carbon layer and the second core carbon layer.

14. The method of claim 13, wherein isotropic etching comprises exposure to radicals of oxygen (O₂), nitrogen (N₂), hydrogen (H₂), ammonia (NH₃), and combinations thereof.

15. The method of claim 13, wherein the first core carbon layer and the second core carbon layer independently comprise a diamond-like carbon material.

16. The method of claim 13, wherein the first support layer and second support layer independently comprise one or more of silicon carbonitride (SiCN), silicon nitride (SiN), and silicon oxide (SiO₂).

17. The method of claim 13, wherein the hardmask layer comprises one or more of silicon oxide (SiOx), silicon carbide (SiC), carbon doped hydrogenated silicon oxide (SiOCH), boron (B), and boron nitride (BN).

18. The method of claim 17, wherein the hardmask layer comprises boron (B) or boron nitride (BN).

19. The method of claim 13, wherein the electrode layer comprises one or more of titanium (Ti), titanium nitride (TiN), tantalum (Ta), and tantalum nitride (TaN).

20. The method of claim 13, wherein the core layer comprises one or more of polysilicon, oxides, carbon doped oxides, silicon dioxide (SiO₂), silicon nitride (SiN), silicon oxide/silicon nitride, carbides, oxycarbides, nitrides, oxynitrides, oxycarbonitrides, polymers, phosphosilicate glass, spin on dielectric (SOD) glass, organosilicate glass (SiOCH), and silicon carbo nitride (SiCN).
